(19) United States
(12) Patent Application Publication
(10) Pub. No.: US 2023/0080380 A1
(43) Pub. Date: Mar. 16, 2023

(54) AUTOMATED GENERATION OF FINITE ELEMENT MESHES FROM LASER SCANNED DATA

(71) Applicant: Northeastern University, Boston, MA (US)

(72) Inventors: Jerome F. Hajjar, Newton, MA (US); Yujie Yan, Nanjing (CN)

(21) Appl. No.: 17/929,580

(22) Filed: Sep. 2, 2022

Related U.S. Application Data
(60) Provisional application No. 63/240,856, filed on Sep. 3, 2021.

(51) Int. Cl. G06F 30/23; G06T 17/20; G06T 19/20

(52) U.S. Cl. CPC G06F 30/23; G06T 17/205; G06T 19/20

(57) ABSTRACT

Embodiments generate finite element meshes (FEMs) representing real-world objects. An example embodiment partitions point cloud data of a real-world object into groups of points where each group corresponds to a component of the real-world object. In turn, such an embodiment generates a respective geometric representation of each group of points and generates a respective FEM of each respective geometric representation generated. The generated FEMs are combined to create a FEM representing the real-world object. Such functionality can be used to build FEMs of as built real-world objects, such as bridges and buildings. These FEMs can, in turn, be used in simulations to determine behavior of the as-built real-world objects and/or determine design changes.

### RELATED APPLICATION

This application claims the benefit of U.S. Provisional Application No. 63/240,856 filed on Sep. 3, 2021. The entire teachings of the above Application are incorporated herein by reference.

### GOVERNMENT SUPPORT

This invention was made with government support under Grant No. 1328816 awarded by the National Science Foundation. The government has certain rights in the invention.

### BACKGROUND

Computer-based modeling of real-world objects is ubiquitous. Such models, e.g., computer-aided design (CAD) solid models and finite element meshes (FEMs) are used in the design, engineering, optimization, and repair of real-world objects.

### SUMMARY

While computer-based modeling is ubiquitous, these models are typically developed prior to the manufacturing and construction of the real-world objects the models represent. However, changes are frequently made to the design of objects during manufacturing and construction. Further, real-world objects deteriorate over time and maintenance is performed that results in changes to the real-world objects. As such, there are often differences between objects as they exist in the real-world and computer-based models, representing the objects, that were built during the design and construction/manufacturing phase. Thus, functionality is needed to create up-to-date computer-based models of real-world objects. Embodiments provide such functionality.

One such embodiment includes a collection of algorithms (i.e., computer-implemented methods) that can automatically convert laser scanned data captured in situ from a real-world object of any type, e.g., a steel girder bridge, into a FEM assembly, which reflects the as-built conditions of the real-world object. In such an embodiment, the FEM assembly is comprised of a suite of conformal all-hexahedron FEMs, each corresponding to an individual structural member (e.g., a steel girder, a cross-frame member, a bolt, or a gusset plate) in the real-world object. In the FEM assembly, connectivity and alignment between the structural members are accurately retained so that the FEMs of each pair of connected structural members are assured to abut each other, but do not overlap with each other. As such, the FEM assembly can be imported directly into finite element analysis software (e.g., Abaqus) and be analyzed without the need for any manual mesh editing. Such technology provides an automated and cost-effective approach for creating as-built finite element models for real-world objects. The as-built models can be used in computer-based engineering (CAE) functionalities, such as refined load rating and evaluation of such real-world objects.

Another embodiment is directed to a computer-implemented method to generate a finite element mesh representing a real-world object. The method partitions point cloud data of a real-world object into groups of points where each group corresponds to a component of the real-world object. In turn, such an embodiment generates a respective geometric representation from each group of points, i.e., a geometric representation representing each group of points. To continue, the method generates a respective FEM of each respective geometric representation generated and combines each generated respective FEM to create a FEM representing the real-world object.

In an embodiment, partitioning the point cloud data includes performing object detection on the point cloud data to determine each component of the real-world object and identifying points corresponding to each determined component as the groups of points.

According to yet another embodiment, generating a respective geometric representation of each group of points comprises, first, processing a given group of points to identify unoccupied space in the given group of points. Second, the identified unoccupied space is classified as empty space or occluded space. Third, each of a plurality of parameterization equations are solved using the given group of points and the unoccupied space classified as empty space or occluded space to identify (i) parameter values for each of the plurality of parameterization equations and (ii) a given parameterization equation from amongst the plurality with a lowest error. Fourth, a geometric representation is generated based on the given parameterization equation with the lowest error and identified parameter values of the given parameterization equation with the lowest error. In one such embodiment, each parameterization equation corresponds to a given geometric shape type.

In another example embodiment, classifying the identified unoccupied space as empty space or occluded space includes classifying the identified unoccupied space as empty if the space was scanned and no point data was collected or classifying the identified unoccupied space as occluded if the space was not scanned and no point data was collected. An example embodiment performs ray-tracing on the given group of points to identify scanned spaces and un-scanned spaces in the given group of points.

In an embodiment each respective geometric representation generated is a solid computer-aided design (CAD) model. Further, in yet another example embodiment, generating a respective FEM of each respective geometric representation includes, for each geometric representation (i) selecting a given mesh generation methodology from amongst a plurality of methodologies, based on an object type represented by the geometric representation and (ii) generating a FEM of the geometric representation using the given mesh generation methodology selected.

An example embodiment combines each generated respective FEM to create a FEM representing the real-world object by (i) combining each generated respective FEM based on spatial relationships of the groups of points, (ii) identifying one or more overlapping mesh elements of the FEMs combined, (iii) deleting the one or more overlapping mesh elements from the FEMs combined to create a blank space in the FEMs combined, and (iv) remeshing the blank space to create the FEM representing the real-world object.

According to an embodiment, the FEM is a conformal hexahedron FEM.

In embodiments, the real-world object may be any real-world object. For instance, in an example embodiment, the real-world object is a bridge. In another embodiment, a given component is a structural member. Example structural members, according to an embodiment, include a deck, a steel girder, a sub-element of a cross-frame, or a sub-element of a transverse diaphragm, amongst other examples.

Yet another embodiment further comprises performing a simulation of the real-world object using the FEM representing the real-world object. Such an embodiment determines, based on results of performing the simulation, at least one of: a design change to the real-world object and structural behavior of the real-world object under load, e.g., various service loads and extreme loads.

Another example embodiment is directed to a computer system for generating finite element meshes of real-world objects. The computer system includes a processor and a memory with computer code instructions stored thereon. In such an embodiment, the processor and the memory, with the computer code instructions, are configured to cause the system to automatically generate meshes according to any embodiment or combination of embodiments described herein.

Yet another embodiment is directed to a computer program product for automatically generating meshes. The computer program product comprises one or more non-transitory computer-readable storage devices and program instructions stored on at least one of the one or more storage devices. The program instructions, when loaded and executed by a processor, cause an apparatus associated with the processor to generate finite element meshes as described herein.

Further details and example embodiments are described below and in the provisional application as filed, U.S. Provisional Application No. 63/240,856 filed on Sep. 3, 2021, the contents of which are herein incorporated by reference in their entirety.

### BRIEF DESCRIPTION OF THE DRAWINGS

The patent or application file contains at least one drawing executed in color. Copies of this patent or patent application publication with color drawing(s) will be provided by the Office upon request and payment of the necessary fee.

The foregoing will be apparent from the following more particular description of example embodiments, as illustrated in the accompanying drawings in which like reference characters refer to the same parts throughout the different views. The drawings are not necessarily to scale, emphasis instead being placed upon illustrating embodiments.

FIG. 1 is a simplified block diagram of an environment in which embodiments may be implemented.

FIG. 2 is a flowchart of a method for generating meshes of real-world objects according to an embodiment.

FIG. 3 is an example of point cloud data that may be used in embodiments.

FIGS. 4A-D are examples of point cloud data with labeled components according to an embodiment.

FIGS. 5A-F are examples of parametric models that may be utilized in embodiments.

FIG. 6 is point cloud data of a real-world object collected using multiple scans according to an embodiment.

FIG. 7A is an example of point cloud data of a real-world object collected from a single scan in an example embodiment.

FIG. 7B illustrates characteristics of the scan used to collect the point cloud data of FIG. 7A.

FIG. 8 is a plot showing ray-tracing results according to an embodiment.

FIG. 9 is a point cloud with occluded elements labeled in an embodiment.

FIGS. 10A-D illustrate elements of a decomposition method applied to a model in an embodiment.

FIGS. 11A-D depict a mesh assembly workflow according to an embodiment.

FIGS. 12A-C depict a workflow of a remeshing/refinement process according to an embodiment.

FIG. 13 is a flowchart of a method embodiment for generating a finite element mesh of a real-world object.

FIG. 14 is a simplified block diagram of a computer system embodiment for generating finite element meshes.

FIG. 15 is a simplified diagram of a computer network environment in which embodiments of the present invention may be implemented.

### DETAILED DESCRIPTION

A description of example embodiments follows.

As described above, computer-based models are ubiquitous, however, these models are typically developed prior to the manufacturing and construction of the real-world objects the models represent. Changes are frequently made to the design of objects during manufacturing and construction. Further, real-world objects change and deteriorate over time and maintenance is performed that results in changes to real-world objects. As such, there are typically differences between real-world objects as they exist and the computer-based models representing the objects that were built during the design and construction/manufacturing phase. Other real-world objects are constructed without any such models and, in other cases, prior models become obsolete or inoperable with current computer-aided design (CAD) and computer-aided engineering (CAE) software. As such, functionality is needed to create computer-based models of real-world objects. Embodiments provide such functionality.

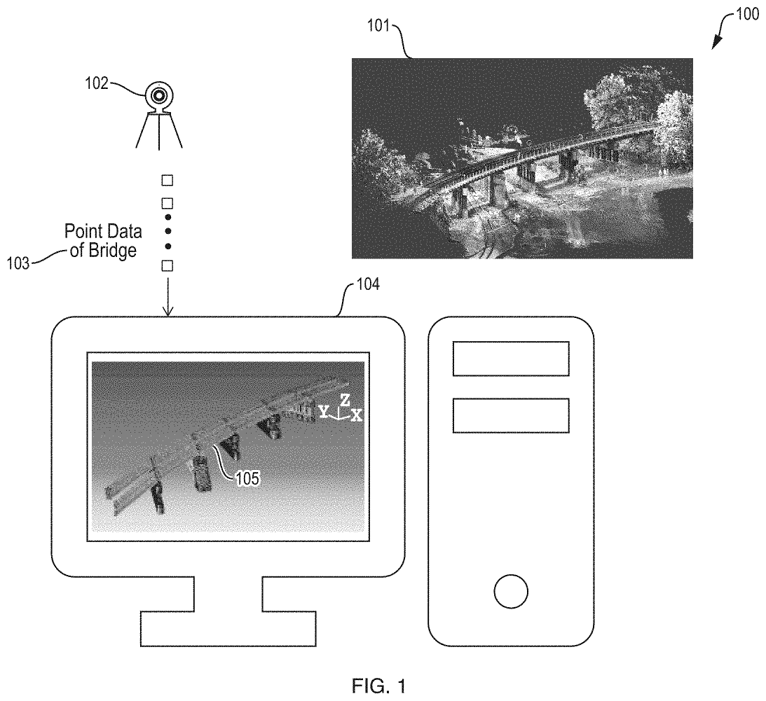

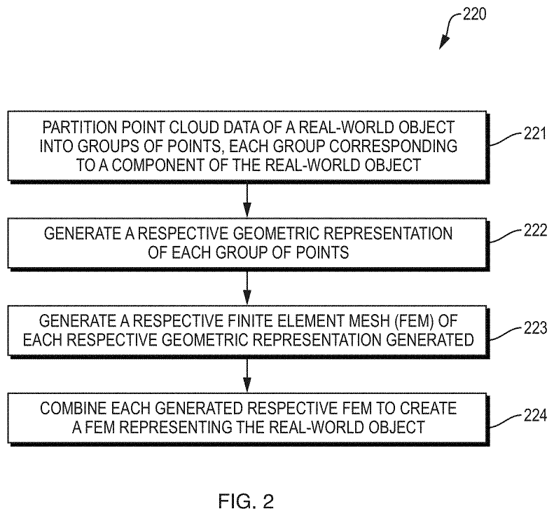

FIG. 1. is a simplified diagram of an example environment 100 in which embodiments may be implemented. The environment 100 includes a real-world object, bridge 101. Embodiments can be employed to create a mesh of the bridge 101 or any other real-world object. In the environment 100 a lidar sensor 102 captures point cloud data 103 of the bridge 101. The point cloud data 103 is sent or otherwise exported to the computing device 104 for processing. The computing device 104 implements the functionality described herein, e.g., the method 220 described hereinbelow in relation to FIG. 2, to generate mesh 105 representing the bridge 101. In an embodiment, the generated mesh 105 is provided in a graphical user interface (GUI) on the computing device 104.

FIG. 2 is a flowchart of a method 220 that is implemented in the environment 100 to generate finite element meshes of real-world objects, e.g., the bridge 101. The method 220 starts by partitioning 221 point cloud data of a real-world object into groups of points where each group corresponds to a component of the real-world object. In turn, the method 220 generates 222 a respective geometric representation from each group of points, i.e., a geometric object representing each group of points. To continue, the method 220 generates 223 a respective FEM of each respective geometric representation generated and combines 224 each generated respective FEM to create a FEM representing the real-world object.

In an embodiment, partitioning 221 the point cloud data includes performing object detection on the point cloud data to determine each component of the real-world object and identifying points corresponding to each determined component as the groups of points.

According to an embodiment, generating 222 a respective geometric representation of each group of points comprises, first, processing a given group of points to identify unoccupied space in the given group of points. Second, the identified unoccupied space is classified as empty space or occluded space. Third, each of a plurality of parameterization equations are solved using the given group of points and the unoccupied space classified as empty space or occluded space to identify (i) parameter values for each of the plurality of parameterization equations and (ii) a given parameterization equation from amongst the plurality with a lowest error. Fourth, a geometric representation is generated based on the given parameterization equation with the lowest error and identified parameter values of the given parameterization equation with the lowest error. In one such embodiment, each parameterization equation corresponds to a given geometric shape type.

Further, in another example embodiment of the method 220, classifying the identified unoccupied space as empty space or occluded space, includes classifying the identified unoccupied space as empty if the space was scanned and no point data was collected or classifying the identified unoccupied space as occluded if the space was not scanned and no point data was collected. An example embodiment performs ray-tracing on the given group of points to identify scanned spaces and un-scanned spaces in the given group of points.

In an embodiment each respective geometric representation generated 222 is a solid computer-aided design (CAD) model. Further, in yet another example embodiment, generating 223 a respective FEM of each respective geometric representation includes, for each geometric representation (i) selecting a given mesh generation methodology from amongst a plurality of methodologies, based on an object type represented by the geometric representation and (ii) generating a FEM of the geometric representation using the given mesh generation methodology selected.

An example embodiment of the method 220 combines 224 each generated respective FEM to create a FEM representing the real-world object by (i) combining each generated respective FEM based on spatial relationships of the groups of points, (ii) identifying one or more overlapping mesh elements of the FEMs combined, (iii) deleting the one or more overlapping mesh elements from the FEMs combined to create a blank space in the FEMs combined, and (iv) remeshing the blank space to create the FEM representing the real-world object.

According to an embodiment, the FEMs, i.e., the FEMs of the geometric representations and the FEM representing the real-world object are conformal hexahedron FEMs.

In embodiments of the method 220, the real-world object may be any real-world object. In an example embodiment, the real-world object is a bridge. In another embodiment, a given component is a structural member. Example structural members, according to an embodiment, include a deck, a steel girder, a sub-element of a cross-frame, or a sub-element of a transverse diaphragm, amongst other examples.

The method 220 may further include performing a simulation of the real-world object using the FEM representing the real-world object. Such an embodiment may determine, based on results of performing the simulation, at least one of: a design change to the real-world object and structural behavior of the real-world object under load, e.g., various service loads and extreme loads. To illustrate, in an example embodiment, behavior under a load may be determined using the FEM in a simulation and this behavior may indicate, e.g., failure of a support column. From this identified failure, it is determined that the support column should be further supported.

Point Data

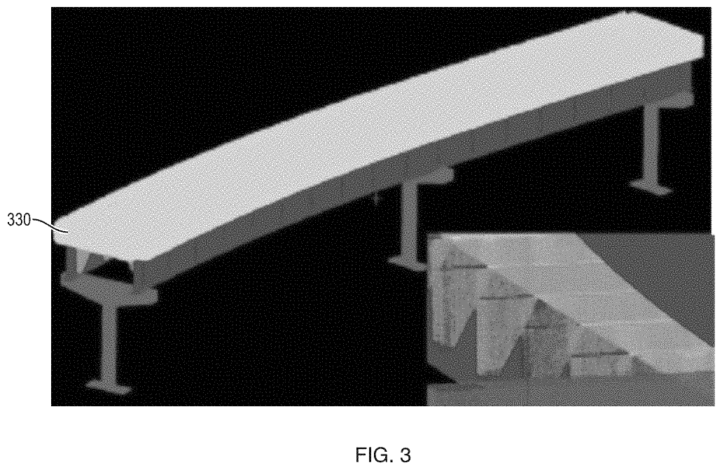

Embodiments start with point cloud data of a real-world object and, from this point cloud data, create a finite element model of the real-world object. FIG. 3 illustrates an example point cloud 330 of a bridge that may be employed in embodiments. The point data, e.g., 330, used in embodiments may be gathered using any technique known in the art. According to an embodiment, the point cloud data is collected using a terrestrial laser scanner (i.e., light detection and ranging (LIDAR) scanner). In another embodiment, the point cloud data is collected using an unmanned aerial vehicle (UAV) based laser scanner.

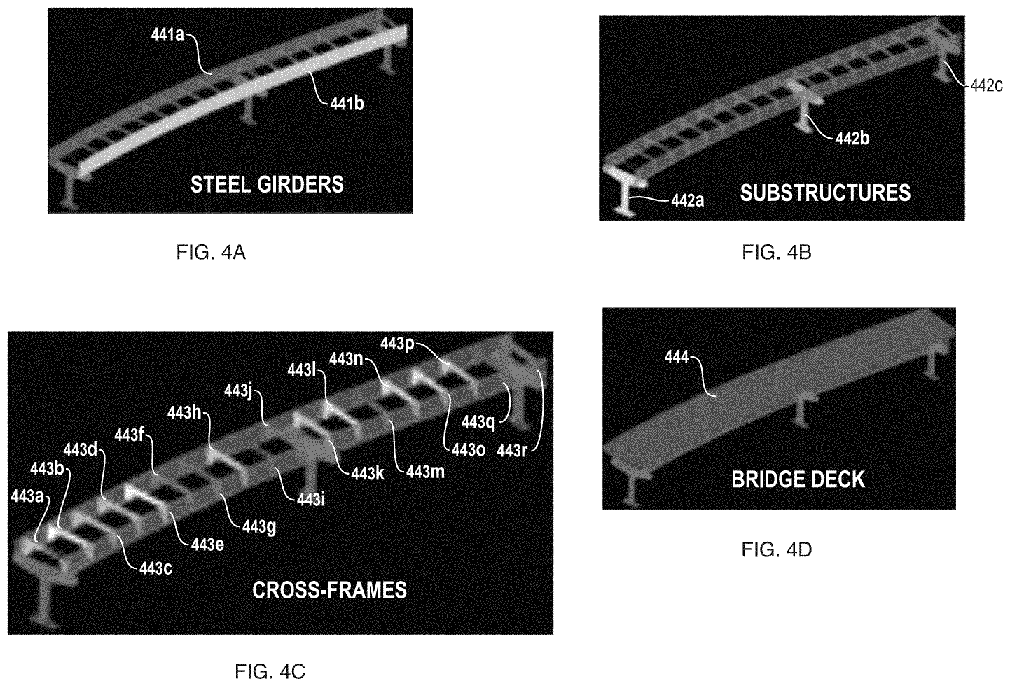

Embodiments take point cloud data, e.g., 330, and partition the point cloud data into groups of points. According to an embodiment, each group of points corresponds to a component of the real-world object. To illustrate, consider the bridge point data 330. In an example embodiment illustrated in FIGS. 4A-D, separate groups of points are identified from amongst the point data 330. Specifically, FIG. 4A shows the point groups 441a-b which are each steel girders. FIG. 4B shows the bridge substructure groups 442a-c. Similarly, FIG. 4C depicts the respective cross-frame groups, 443a-r, and FIG. 4D illustrates the bridge deck group 444.

Point Data Partitioning

Embodiments may use a variety of different techniques, alone or in combination, to partition point cloud data into groups. For instance, one such embodiment performs object detection on the point cloud data to determine each component of the real-world object. In turn, groups corresponding to each determined component are identified. Further, embodiments may partition point cloud data into groups by implementing the functionality described in the document entitled “Automated extraction of structural elements in steel girder bridges from laser point clouds,” which is part of U.S. Provisional Application No. 63/240,856 filed on Sep. 3, 2021. Further, it is noted that while the foregoing document is related to steel girder bridges, said document, and embodiments described herein, are not limited to steel girder bridges. Instead, embodiments can utilize the functionality described herein and the document entitled “Automated extraction of structural elements in steel girder bridges from laser point clouds,” for any real-world object with heuristic data that indicates sub-components of the real-world object and interrelations between the sub-components. As such, the heuristic-based approach for point cloud partitioning described in the document entitled “Automated extraction of structural elements in steel girder bridges from laser point clouds,” can be extended and applied to point cloud data of structures other than steel girder bridges. Such extension can be done using additional data, e.g., additional expert knowledge or other such heuristics.

For example, for truss bridges, in order to extract the trusses, data which defines the spatial relationship between trusses and the bridge deck can be used to extract the trusses from the point data. However, once the trusses are extracted, since the trusses are similar to cross-frames in steel girder bridges, embodiments can use the approaches described herein to partition the trusses into individual steel members.

Geometric Modeling of Point Data

Once embodiments identify groups of points, i.e., collections of points representing sub-components (e.g., a steel girder, a cross-frame, etc.) of the real-world object, embodiments generate geometric models for each group of points. In other words, embodiments generate a respective geometric model representing each respective group of points.

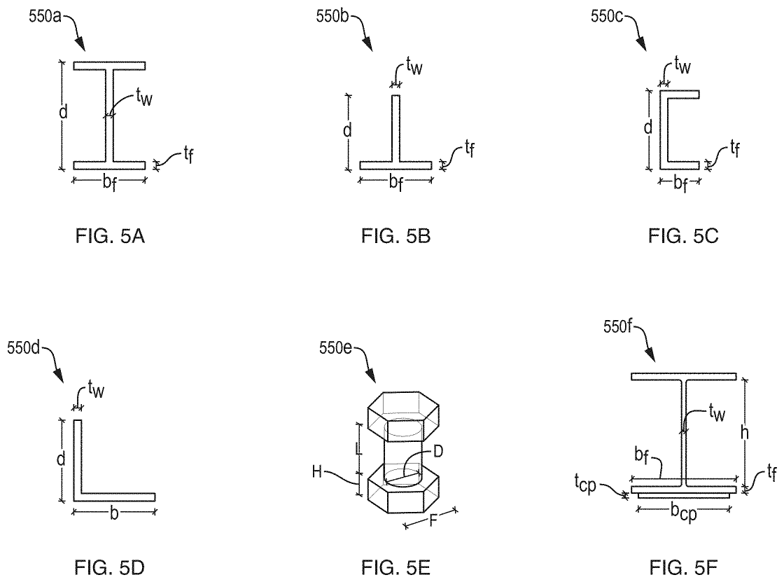

In an example embodiment, each point group, i.e., point segment, associated with a sub-component, is processed to establish a parametric representation that encodes the complete geometry of the corresponding structural component. Target types of parametric models 550a-f, according to an embodiment, are illustrated in FIGS. 5A-F, respectively. According to an embodiment, given a point segment, the corresponding parametric representation is established by selecting a parametric model and optimizing corresponding parameter values of the selected parametric model based on the point segment.

Another embodiment tests multiple parametric models (which each have a corresponding parametric equation) for each group of points. To illustrate, consider an example of a given group of points. In such an embodiment, parameter values for each type of parametric model are determined for the given group of points. The determined parameter values indicate the features of each type of parametric model that best fits the given group of points. In turn, the error between the given group of points and each parametric model with the determined parameter values is determined. The parametric model (with its accompanying parameter values) with the lowest error is selected as the parametric model that represents the given group of points.

In another embodiment, before a geometric, i.e., parameter based, model for a group of points is determined, the group of points is further processed to identify the points in the group to be used for purposes of generating the geometric model.

Based on point cloud data, the space containing a captured scene (i.e., the real-world object and surrounding environment) can be classified into occupied spaces and unoccupied spaces. In an embodiment, the unoccupied spaces are further classified into occluded spaces and empty spaces. The identification (i.e., classification) of occluded spaces is utilized to improve the robustness of object detection and modeling of the missing data (e.g., resulting from occlusion) in created point cloud maps. In an embodiment, occluded spaces and empty spaces are distinguished using a ray-tracing process.

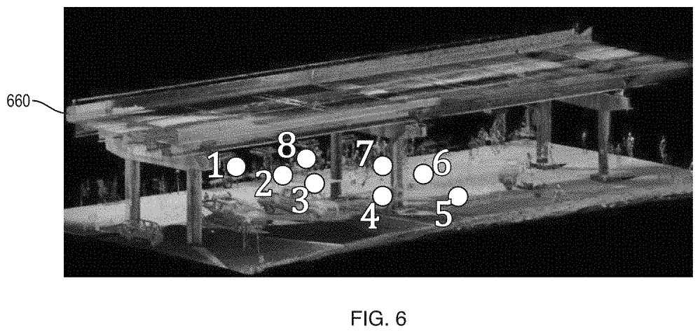

In such an embodiment, given a real-world object (or more generally a scene) scanned by N stationary scans {LS₁, LS₂, . . . LS_{N}}, as shown in FIG. 6 (illustrating the point cloud data 660 collected by the scans conducted at locations 1-8), the ray tracing processing is implemented through two primary steps: (1) for each scan, a series of rays originating from the scanner position are created and subsequently traced to compute the location of the occupied spaces and (2) the unoccupied spaces are processed and classified into empty spaces and occluded spaces.

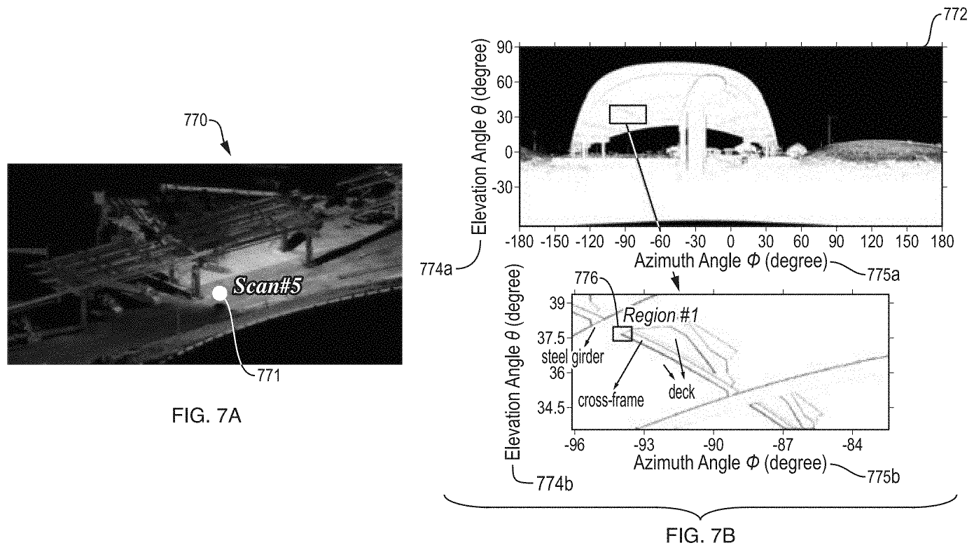

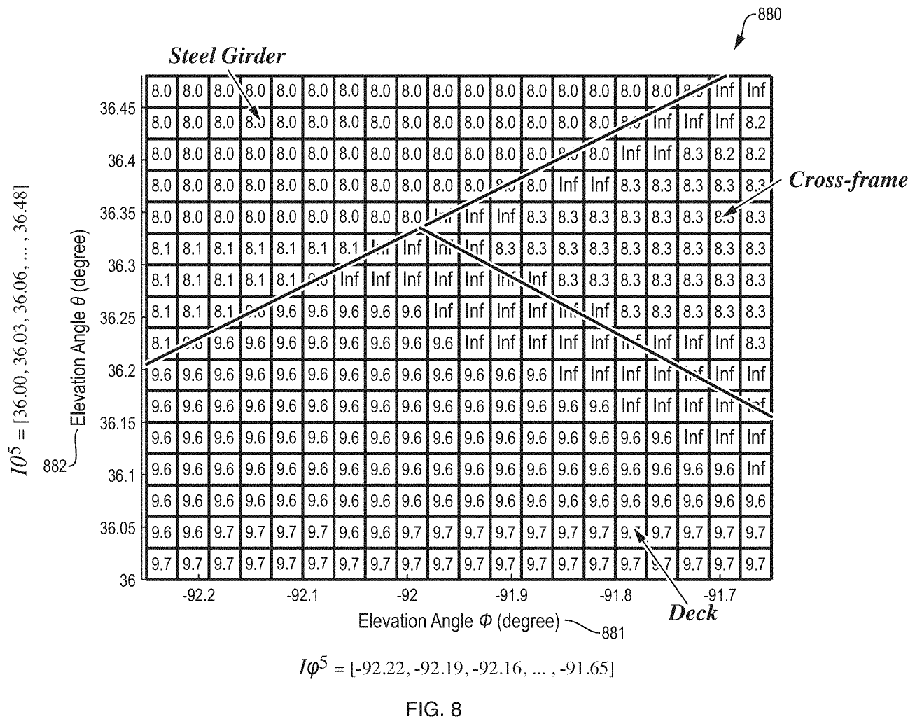

In the first step (creating and tracing rays to determine the occupied spaces), given a point cloud collected by a specific scan LS_{K} and the coordinates of the scanner position, the proposed method starts with transforming point data [x, y, z] of each point from the scan to a spherical coordinate system [φ, θ, r] that is centered at the scanner position, where φ is the azimuth angle, θ is the elevation angle, and r is the distance from the point to the scanner position. FIG. 7A illustrates an example specific scan 770 collected with a scanner at the position 771. FIG. 7B are images 772 and 773 showing the elevation angles θ 774a-b and azimuth angles 775a-b. Subsequently, the φ-θ plane is subdivided into regularly distributed grids. The size of the grids is determined based on the angular resolution of the laser scanner as presented in Table 1.

TABLE 1
Calibrated Grid Sizes For Scanner Resolution Settings

| | Equivalent Angular | |
|---|---|---|
| Resolution Setting | Resolution (degree) | Grid Size (degree) |
| ½ | 0.018° | 0.03° |
| ¼ | 0.036° | 0.07° |
| ⅛ | 0.072° | 0.13° |

Within each grid, the bounded point data are identified and the corresponding r values are extracted. The minimum r value is then assigned to the grid. In other words, in an embodiment, each grid has multiple points and each point as an associated r value. In an embodiment, the point with the lowest r value is selected. For grids with no bounded points, a inf value is assigned. Finally, the results are stored using the following vectors and matrix: (i) Iφ^{K}−1×m vector containing the φ intervals of the grids, (ii) Iθ^{K}−1×n vector containing the 0 intervals of the grids, and (iii) Rmin^{K}−m×n matrix containing the minimum r value in each grid.

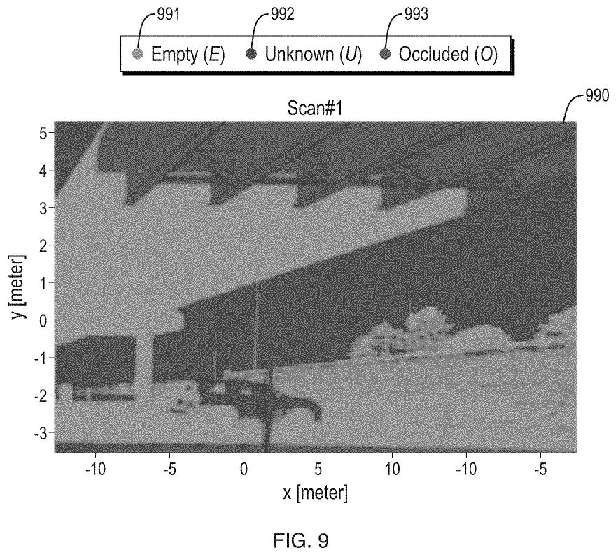

An example highlighting the results 880 of the region 776 in FIG. 7B is shown in FIG. 8. For this isolated region 776, the azimuth angles 881 vary from −92.22° to −91.65° and the elevation angles 882 vary from 36.00° to 36.48°. The region is divided into 20×16 regularly distributed grids with a size of 0.03°. As a result of the first step, Iφ⁵ is a 20×1 vector and Iθ⁵ is a 16×1 vector. Rmin⁵ is a 20×16 matrix containing the minimum r value in each grid.

Once all scans {LS₁, LS₂, . . . LS_{N}} are processed through the abovementioned step, any query (unoccupied) spaces can now be classified into empty spaces (E) and occluded spaces (O) automatically. Given the coordinates of the query (unoccupied) spaces [xᵢ,yᵢ,zᵢ](∀i=1, 2 . . . n—total number of query spaces), for each scan LS_{K}, these query spaces are transformed to the local spherical coordinate system [φᵢ^{K},θᵢ^{K},rᵢ^{K}] (as mentioned in the previous step). Based on Iφ^{K} and Iθ^{K}, the corresponding grids of these query spaces are identified and the corresponding minimum r values are extracted from Rmin^{K}. Each query space is assigned with one of the three labels: empty space (E), occluded space (O), unknown space (U). The labels are assigned to each query point as follows:

Lᵢ^{K}—label of i-th query space in scan K, ∀K=1, 2, . . . , N, ∀i=1, 2, . . . n
Lᵢ^{K}=E, if rᵢ^{K}<Rminᵢ^{K} and Rminᵢ^{K}≠inf
Lᵢ^{K}=O, if rᵢ^{K}K≥Rminᵢ^{K} and Rminᵢ^{K}≠inf
Lᵢ^{K}=U, if Rminᵢ^{K}=inf

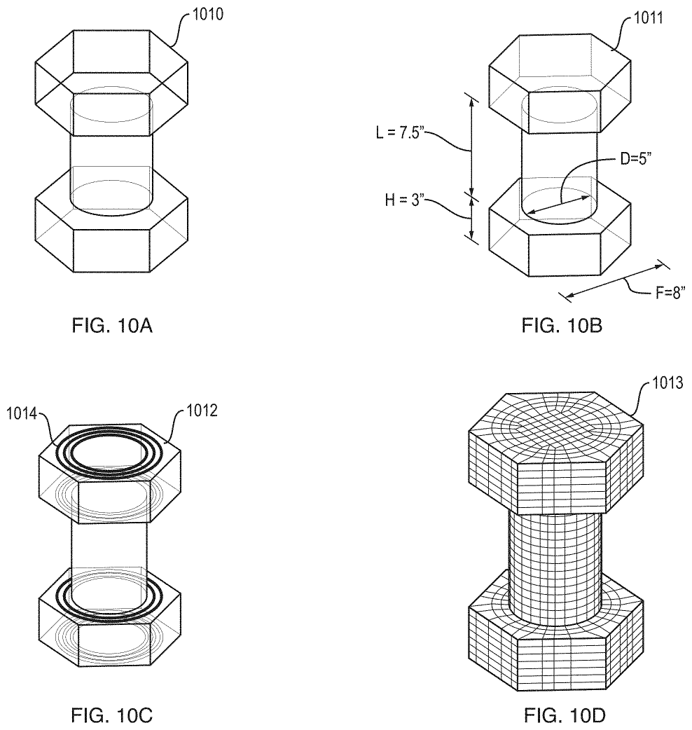

After the ray-tracing process, each query (unoccupied) space has N labels {Lᵢ¹, Lᵢ², . . . , Lᵢ^{N}}. Finally, the query space is determined as: 1) empty space (E) if this space is identified as an empty space in one or more scans; 2) unknown space (U) if this is space is identified as an unknown space in every scan; 3) occluded space (O) otherwise. An example of the final occlusion labels for the point data 990 is presented in FIG. 9. In FIG. 9, the different shading of the point data 990 shows the empty 991 areas, unknown areas 992, and occluded areas 993.

In embodiments that identify the occluded areas, the occluded areas are utilized in point groupings, i.e., segments, in the geometric model generation functionality. In this way, embodiments create more accurate geometric models for each group of points. An embodiment uses a cost function to define coherence between the occlusion labels and geometric models. Briefly, the cost function measures a number of occluded spaces located outside the geometric model and number of empty spaces located inside the geometric model. By minimizing the cost function, an embodiment derives an optimal geometric model.

Element Level Mesh Generation

Regardless, of whether the foregoing occlusion determination is implemented, after capturing and partitioning point data into groups, i.e., point segments, representing individual elements, and creating explicit geometric representations of each group, embodiments further process the geometric representations to create finite element meshes.

An embodiment first processes the explicit geometric representations of the structural elements independently to create conformal element-level FE meshes. In this process, the complete geometric representations are classified into four categories: (1) 3D parametric objects, such as bolts and cross-frame members, (2) sweep-based objects with parametric section profiles, such as steel girders, (3) sweep-based objects with generic cross-section profiles, such as bridge decks and the columns and caps of hammerhead piers, and (4) generic objects, such as masonry piers. Based on the classifications, such an embodiment implements one of four different mesh generation techniques as described in the document entitled “Automated Damage Assessment and Structural Modeling of Bridges with Visual Sensing Technology” of U.S. Provisional Application No. 63/240,856 filed on Sep. 3, 2021.

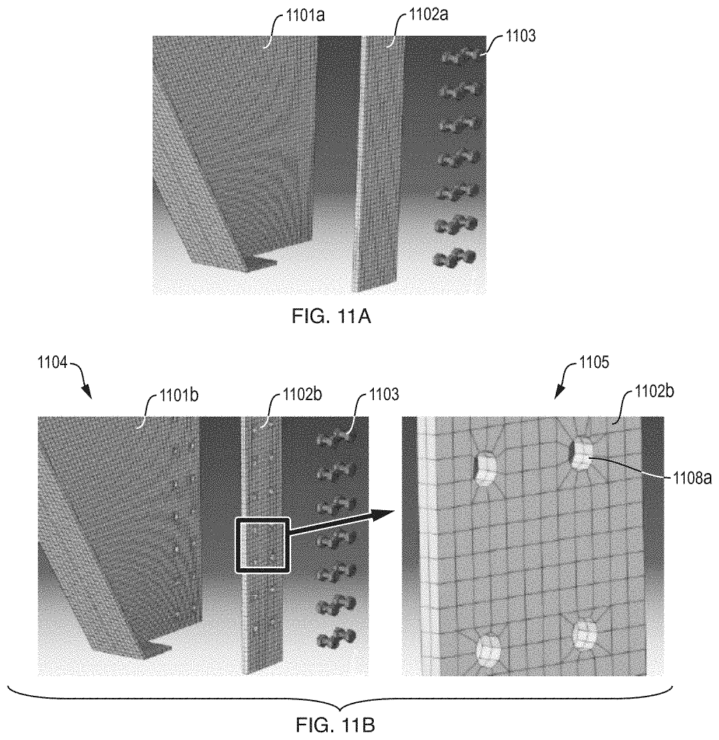

In the example of 3D parametric objects, each type of parametric model has an associated geometry decomposition strategy that is applied to the model. The decomposition strategies are invariant to parameter values and are used to automatically partition the parametric models into convex primitives. Using techniques known to those of skill in the art, these convex primitives are mapped with a standard cube with regularly distributed hexahedrons to create a finite element mesh. FIGS. 10A-D illustrate stages of the foregoing functionality. Specifically, FIG. 10A illustrates an example segmented point cloud 1010. FIG. 10B illustrates a parameter model 1011 generated from the point cloud 1010. FIG. 10C. illustrates the geometry decomposition 1012 where the parameter model 1011 is partitioned into convex primitives. Convex primitives share similar characteristics with convex polyhedrons, but allow curved surfaces. The cylinders, e.g., 1014, in FIG. 10C are a type of convex primitive. FIG. 10D illustrates the resulting mesh 1013 generated from the convex primitives of FIG. 10C.

Mesh Assembly

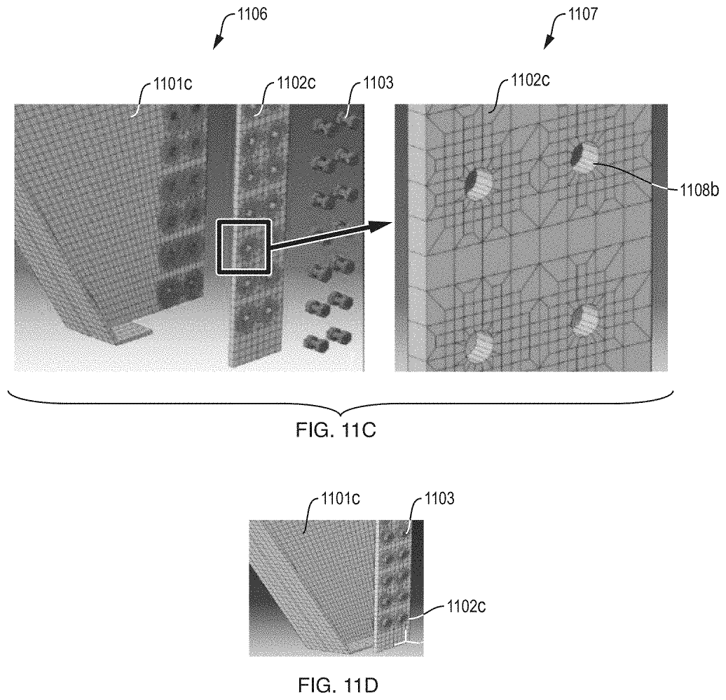

Once FE meshes are created for components, e.g., structural elements, the meshes are put together automatically to create the assembled FE mesh for the entire real-world object. Since components are meshed independently, mesh overlapping may occur in the assembled FE mesh. This is particularly the case for bolted connections. For example, as shown in FIG. 11A, mesh overlapping will occur when assembling clamped components 1101a and 1102a with the bolts 1103. To address this issue, as shown in FIG. 11B in the view 1104 and zoomed in view 1105, the original FE meshes 1101a and 1102a of the clamped components are remeshed to create the meshes 1101b and 1102b with bolt holes, e.g., 1108a. In this way the resultant meshes 1101b and 1102b abut, but do not overlap the mesh of the bolts 1103.

In addition, to enhance the accuracy of the resultant mesh in capturing the geometry of the bolt holes, it is optional to have the elements surrounding the bolt shank refined locally. This local refining is shown in the views 1106 and 1107 of FIG. 11C where the bolt holes, e.g., 1108b, on the components 1101c and 1102c are refined.

After the refining or after creating the bolt holes, if the refining is not implemented, the elements 1101c and 1102c are assembled with the bolts 1103 as shown in FIG. 11D.

By assigning the element nodes around the bolt shank to refinement nodes, an embodiment can automatically complete the refinement using a local refinement method, such as those known to those of skill in the art.

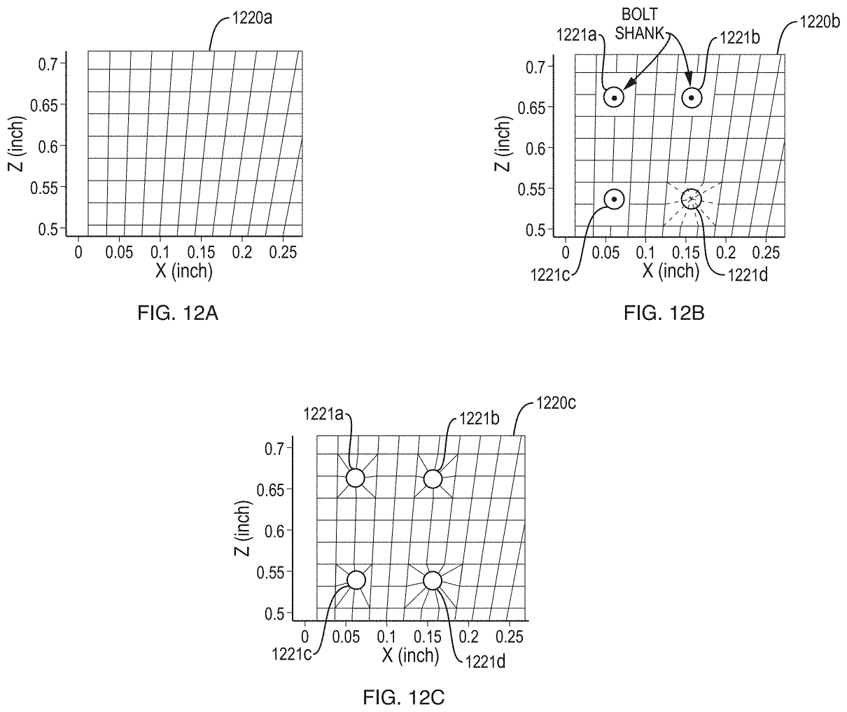

FIGS. 12A-C present a workflow of a remeshing/refinement process according to an embodiment. Given the FE mesh 1220a of a clamped component as shown in FIG. 12A, the remeshing process starts with deleting the element nodes that fall inside the bolt shanks 1221a-d. The FE mesh 1220b is then updated to remove the elements that are associated with deleted nodes as shown in FIG. 12B. For each bolt shank 1221a-d, the newly produced boundary nodes surrounding the bolt shank 1221a-d are identified. For each boundary node, a search direction, which is perpendicular to the bolt shank, is assigned. Accordingly, the intersection of the search direction and the bolt shank 1221a-d is computed as the correspondence of the boundary node. This is illustrated in FIG. 12B in relation to the bolt shank 1221d where the dashed lines indicate the search directions and the intersections between these dashed lines and the bolt shank 1221d (the circle) are the corresponding points. Finally, by connecting the boundary nodes with their correspondences, a new layer of hexahedral FE meshes are added so that the resultant FE mesh abuts the bolt shank seamlessly. This in shown on the mesh 1220c where mesh elements abut the bolt shanks 1221a-d.

Example Steel Bridge Implementation

In engineering analysis of complex bridges, such as steel girder bridges, much more time is spent on creating an adequate mesh than obtaining the solution once the FE model is created. Substantial human inspections and interventions are required to ensure the connectivity and alignment between the structural elements, so that the assembled element-level FE meshes abut each other, but do not overlap. This is particularly the case for steel girder bridges, which are ubiquitous transportation infrastructure in the United States. Steel girder bridges are comprised of a collection of small and slender sub-elements that need to be aligned with high precision. Thus, in order to facilitate the modeling of such bridges, one such embodiment implements a parametric representation, based on the OpenBrIM (Bartholomew et al., 2015), to model the steel superstructure components of a steel girder bridge. Both the dimensions and the spatial relationships of the sub-elements are defined by a series of parameters. In addition, by having the parameters assigned with appropriate values, an embodiment automatically generates and assembles element-level conformal FE meshes. The assembled FE meshes can be directly imported into Abaqus, or other such simulation software, for FE analysis, after being assigned with appropriate loading conditions, boundary conditions, interaction definitions, and material properties.

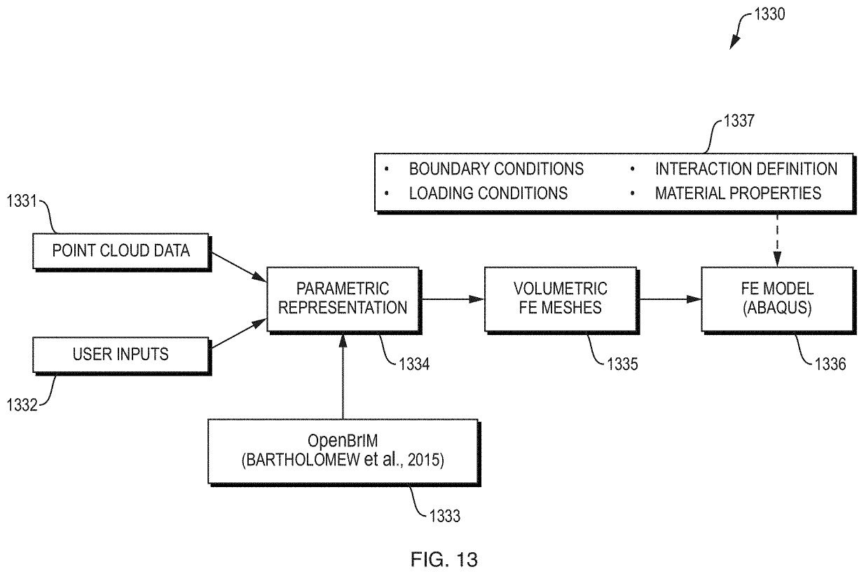

FIG. 13 illustrates one such example method 1330 for generating a finite element mesh of a steel girder bridge. The method 1330 begins with point cloud data 1331 of the bridge and user inputs 1332. To have a valid high-fidelity finite element model (one that can be used for FE analysis), the structural system should be modeled completely. However, the complete structural system cannot always be reconstructed from laser point clouds. Thus, in an embodiment, the user inputs 1332 are parameters that cannot be obtained from laser point cloud data 1331. As such, user input data 1332 varies depending on the quality of the laser point cloud data 1331. For example, if a portion of the structural system is occluded in the point cloud data 1331, the geometry of this portion is provided as part of the user input 1332. In another example, if the noise level of the point cloud data 1331 is high, bolts may not be detectable in the point cloud 1331 and, thus, geometry and distributions of the bolts is included in the user inputs 1332.

The point cloud data 1331 and user inputs 1332 are used with the OpenBrIM functionality 1333 to create parametric representations 1334 of each element of the steel girder bridge. Volumetric finite element meshes 1335 representing each element of the bridge are then generated using the parametric representations 1334. The individual meshes 1335 are then assembled to create the finite element model 1336 of the entire bridge. In turn, analyses can be performed in any number of software simulation suites, e.g., Abaqus, using the finite element model 1336 and any additional input data 1337, e.g., boundary conditions, loading conditions, interaction definitions, and material properties, amongst other examples.

Embodiments take registered point clouds, e.g., collected by terrestrial laser scanners, as inputs. For terrestrial-based laser scanning, in most cases, multiple stationary scans are performed to observe the structural system from different points of view. Each resultant point cloud (from a single stationary scan) has its own coordinate system. The registration of point clouds is aimed to align these point clouds and transform them to a globally consistent coordinate system. Provided a small number of parameter values that define the specification of the employed laser scanner, e.g., angular resolution, range, and noise characteristics of the laser scanner, and the desired mesh sizes, embodiments automatically create a finite element mesh assembly for a real-world object. Embodiments may also create a corresponding input file for simulation/CAE software, which can be imported into such software, e.g., Abaqus, directly for further assignment of material properties, interaction properties, and loading conditions. In an embodiment, the FE mesh assembly is created through a four-step process. In the first step, an object detection algorithm is applied to partition the registered point cloud into a collection of point segments, each corresponding to an individual structural member. Each point segment is then processed separately to create a complete geometric representation for the corresponding structural member. A challenge in this step is to address the missing data and partial occlusions in the point segments, which is particularly common for steel members with thin geometry. In an embodiment, this is addressed by leveraging parametric models and 3D occlusion labeling. Thereafter, each of the reconstructed geometric representations is automatically converted into an all-hexahedron conformal finite element mesh. In order to optimize the resultant mesh quality, various mesh generation strategies are used and are implemented automatically depending on the geometric characteristics of the structural member to be meshed. Finally, the FE meshes of the structural members are assembled based on their spatial relationships to create a FE mesh assembly for the bridge. Since the finite element meshes of the structural members are created independently, mesh overlapping may occur in the mesh assembly, such as at the interface between bolts and the connected structural members. As such, a remeshing step is applied in an embodiment to automatically detect regions with overlapped FE meshes in the mesh assembly and, subsequently, re-mesh these regions.

Example Features and Advantages

Embodiments provide an object detection methodology that automatically detects individual structural members in real-world objects from laser scanned data. In an embodiment, the target structural members include the bridge deck, steel girders, and the sub-elements of various types of cross-frames (e.g., X-type, K-type, beam-type) and transverse diaphragms. Embodiments also implement a geometric modeling process that automatically reconstructs the complete geometry of the structural members from laser scanned data with partial occlusions, which is particularly common for steel elements with thin geometry. Another embodiment automatically creates a conformal all-hexahedron FE mesh for each structural element based on the reconstructed complete geometry where the quality of the resultant FE meshes are assured to comply with the recommended mesh quality for FE analysis. Embodiments also automatically put together the FE meshes to create a mesh assembly and create an Abaqus input file that can be imported into Abaqus/CAE directly. In embodiments the mesh assembly retains the connectivity and alignment between the structural elements and can be used for analysis without the need for any manual mesh editing. An embodiment relies upon expert knowledge as heuristics to reinforce the connectivity and alignment between structural components. To illustrate, take a X-type cross-frame as an example, the leg of the L-section cross-frame is always in plane with the connected stiffener and gusset plates. This information is used to combine meshes representing the L-section, stiffener, and gusset plates in accordance with the aforementioned configuration.

Advantageously, embodiments provide an automated end-to-end workflow for the as-built FE mesh generation of complex bridge superstructures from laser scanned data, while existing methods either only address simple blocky structures (Hinks et al., 2013; Castellazzi et al., 2015) or require substantial human interventions in data interpretation and processing (Conde-Carnero et al., 2016; Bassier et al., 2019; Abbate et al., 2020). The object detection methodology implemented in embodiments provides a solution to automated detection and segmentation of structural members in steel girder bridges from laser scanned data, while the related methods in the literature address structures that are quite different from steel girder bridges (Song and Huber, 2015; Riveiro et al., 2016; Lu et al., 2019). The geometric modeling processes of embodiments provide a robust approach for reconstructing complete geometry information of structural members by fully exploiting the information gathered from the laser scans, including occluded spaces and empty spaces. A ray tracing-based occlusion labeling step is utilized in the geometric modeling process to gather this information from the captured laser point clouds automatically. In this way, by integrating this information in the geometric modeling process, embodiments are able to address a wide range of occlusion levels and thus provide an improvement over the existing methods (Laefer and Truong-Hong, 2017; Lu and Brilakis, 2019; Yang et al., 2020; Trias et al., 2021), which are mostly based solely on captured laser points.

Computer Support

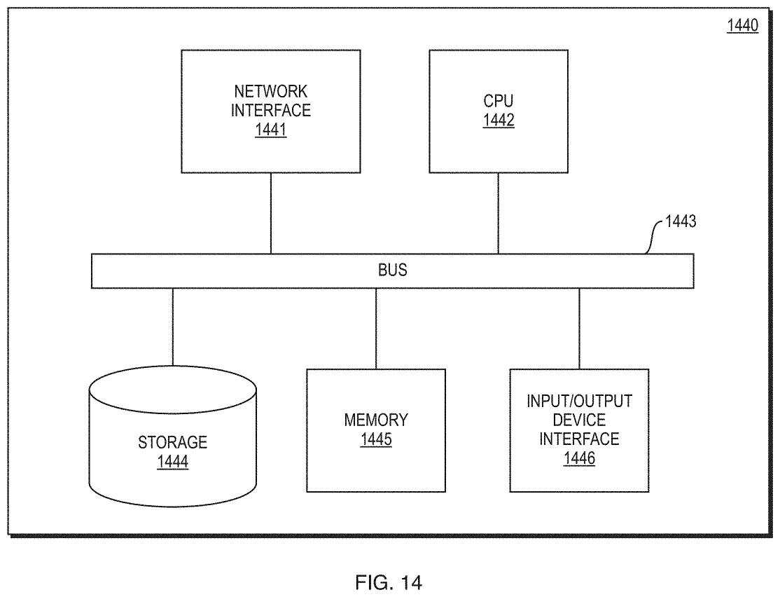

FIG. 14 is a simplified block diagram of a computer-based system 1440 that may be used to implement any variety or combination of the embodiments of the present invention described herein. The system 1440 comprises a bus 1443. The bus 1443 serves as an interconnect between the various components of the system 1440. Connected to the bus 1443 is an input/output device interface 1446 for connecting various input and output devices such as a keyboard, mouse, display, speakers, etc. to the system 1440. A central processing unit (CPU) 1442 is connected to the bus 1443 and provides for the execution of computer instructions implementing embodiments. Memory 1445 provides volatile storage for data used for carrying out computer instructions implementing embodiments described herein, such as those embodiments previously described hereinabove. Storage 1444 provides non-volatile storage for software instructions, such as an operating system (not shown) and embodiment configurations, etc. The system 1440 also comprises a network interface 1441 for connecting to any variety of networks known in the art, including wide area networks (WANs) and local area networks (LANs).

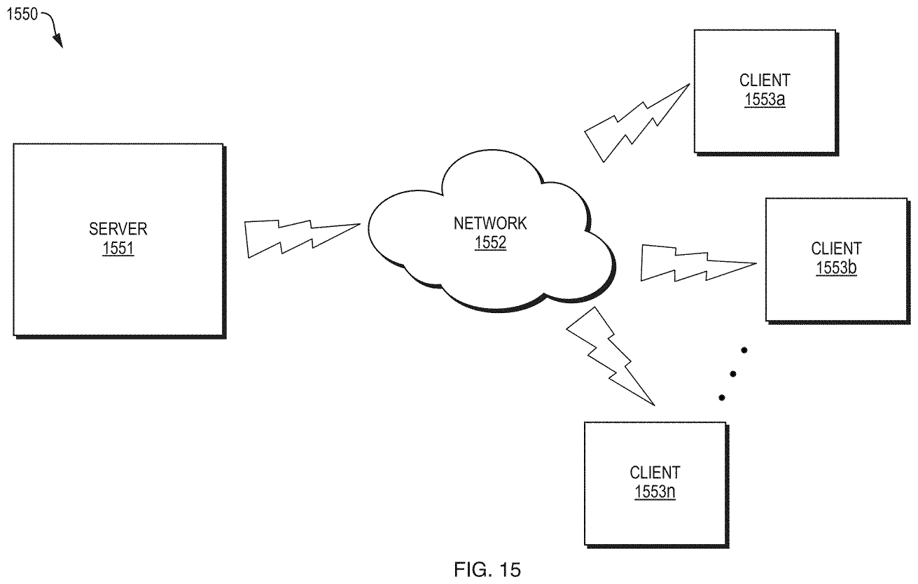

It should be understood that the example embodiments described herein may be implemented in many different ways. In some instances, the various methods and systems described herein may each be implemented by a physical, virtual, or hybrid general purpose computer, such as the computer system 1440, or a computer network environment such as the computer environment 1550, described herein below in relation to FIG. 15. The computer system 1440 may be transformed into the systems that execute the methods described herein, for example, by loading software instructions into either memory 1445 or non-volatile storage 1444 for execution by the CPU 1442. One of ordinary skill in the art should further understand that the system 1440 and its various components may be configured to carry out any embodiments or combination of embodiments of the present invention described herein. Further, the system 1440 may implement the various embodiments described herein utilizing any combination of hardware, software, and firmware modules operatively coupled, internally, or externally, to the system 1440.

FIG. 15 illustrates a computer network environment 1550 in which an embodiment of the present invention may be implemented. In the computer network environment 1550, the server 1551 is linked through the communications network 1552 to the clients 1553a-n. The environment 1550 may be used to allow the clients 1553a-n, alone or in combination with the server 1551, to execute any of the embodiments described herein. For non-limiting example, computer network environment 1550 provides cloud computing embodiments, software as a service (SAAS) embodiments, and the like.

Embodiments or aspects thereof may be implemented in the form of hardware, firmware, or software. If implemented in software, the software may be stored on any non-transient computer readable medium that is configured to enable a processor to load the software or subsets of instructions thereof. The processor then executes the instructions and is configured to operate or cause an apparatus to operate in a manner as described herein.

Further, firmware, software, routines, or instructions may be described herein as performing certain actions and/or functions of the data processors. However, it should be appreciated that such descriptions contained herein are merely for convenience and that such actions in fact result from computing devices, processors, controllers, or other devices executing the firmware, software, routines, instructions, etc.

It should be understood that the flow diagrams, block diagrams, and network diagrams may include more or fewer elements, be arranged differently, or be represented differently. But it further should be understood that certain implementations may dictate the block and network diagrams and the number of block and network diagrams illustrating the execution of the embodiments be implemented in a particular way.

Accordingly, further embodiments may also be implemented in a variety of computer architectures, physical, virtual, cloud computers, and/or some combination thereof, and thus, the data processors described herein are intended for purposes of illustration only and not as a limitation of the embodiments.

The teachings of all patents, published applications and references cited herein are incorporated by reference in their entirety.

While example embodiments have been particularly shown and described, it will be understood by those skilled in the art that various changes in form and details may be made therein without departing from the scope of the embodiments encompassed by the appended claims.

### REFERENCES

1. Abbate, E., Invernizzi, S. and Spanò, A. (2020). “HBIM parametric modelling from clouds to perform structural analyses based on finite elements: a case study on a parabolic concrete vault,” Applied Geomatics, pp 1-18.
2. Bassier, M., Hardy, G., Bejarano-Urrego, L., Drougkas, A., Verstrynge, E., Van Balen, K. and Vergauwen, M. (2019). “Semi-automated creation of accurate FE meshes of heritage masonry walls from point cloud data” Structural Analysis of Historical Constructions, pp. 305-314.
3. Castellazzi, G., D'Altri, A. M., Bitelli, G., Selvaggi, I. and Lambertini, A. (2015). “From Laser Scanning to Finite Element Analysis of Complex Buildings by Using a Semi-Automatic Procedure,” Sensors (Basel), Vol. 15, No. 8, pp. 18360-18380.
4. Conde-Carnero, B., Riveiro, B., Arias, P. and Caamaño, J. C. (2016). “Exploitation of Geometric Data provided by Laser Scanning to Create FEM Structural Models of Bridges,” Journal of Performance of Constructed Facilities, Vol. 30, No. 3, p. 04015053.
5. Hinks, T., Carr, H., Truong-Hong, L. and Laefer, D. F. (2013). “Point Cloud Data Conversion into Solid Models via Point-Based Voxelization,” Journal of Surveying Engineering, Vol. 139, No. 2, pp. 72-83.
6. Laefer, D. F. and Truong-Hong, L. (2017). “Toward Automatic Generation of 3D Steel Structures for Building Information Modelling,” Automation in Construction, Vol. 74, pp. 66-77.
7. Lu, R. and Brilakis, I. (2019). “Digital Twinning of Existing Reinforced Concrete Bridges from Labelled Point Clusters,” Automation in Construction, Vol. 105, p. 102837.
8. Lu, R., Brilakis, I. and Middleton, C. R. (2019). “Detection of Structural Components in Point Clouds of Existing RC Bridges,” Computer-Aided Civil and Infrastructure Engineering, Vol. 34, No. 3, pp. 191-212.
9. Riveiro, B., DeJong, M. J. and Conde, B. (2016). “Automated Processing of Large Point Clouds for Structural Health Monitoring of Masonry Arch Bridges,” Automation in Construction, Vol. 72, pp. 258-268.
10. Song, M. and Huber, D. (2015). “Automatic Recovery of Networks of Thin Structures,” 2015 International Conference on 3D Vision, Lyon, France, Oct. 19-22, 2015.
11. Trias, A., Yu, Y., Gong, J. and Moon, F. L. (2021). “Supporting quantitative structural assessment of highway bridges through the use of LiDAR scanning,” Structure and Infrastructure Engineering, pp. 1-12.
12. Yang, L., Cheng, J. C. P. and Wang, Q. (2020). “Semi-automated generation of parametric BIM for steel structures based on terrestrial laser scanning data,” Automation in Construction, Vol. 112.13.
13. Bartholomew, M., Blasen, B. and Koc, A. (2015). “Bridge information modeling (BrIM) using open parametric objects,” Report No. FHWA-HIF-16-010, Federal Highway Administration, Office of Infrastructure, United States.

What is claimed is:

1. A method for generating a finite element mesh (FEM) representing a real-world object, the method comprising:
partitioning point cloud data of a real-world object into groups of points, each group corresponding to a component of the real-world object;
generating a respective geometric representation of each group of points;
generating a respective finite element mesh (FEM) of each respective geometric representation generated; and
combining each generated respective FEM to create a FEM representing the real-world object.

2. The method of claim 1 wherein partitioning the point cloud data includes:
performing object detection on the point cloud data to determine each component of the real-world object; and
identifying points corresponding to each determined component as the groups of points.

3. The method of claim 1 wherein generating a respective geometric representation of each group of points comprises:
processing a given group of points to identify unoccupied space in the given group of points;
classifying the identified unoccupied space as empty space or occluded space;
solving each of a plurality of parameterization equations using the given group of points and the unoccupied space classified as empty space or occluded space to identify (i) parameter values for each of the plurality of parameterization equations and (ii) a given parameterization equation from amongst the plurality with a lowest error; and
generating a geometric representation based on the given parameterization equation with the lowest error and identified parameter values of the given parameterization equation with the lowest error.

4. The method of claim 3 wherein each parameterization equation corresponds to a given geometric shape type.

5. The method of claim 3 wherein, in classifying the identified unoccupied space as empty space or occluded space, the method further comprises:
classifying the identified unoccupied space as empty if the space was scanned and no point data was collected; or
classifying the identified unoccupied space as occluded if the space was not scanned and no point data was collected.

6. The method of claim 5 further comprising:
performing ray-tracing on the given group of points to identify scanned spaces and un-scanned spaces in the given group of points.

7. The method of claim 1 wherein each respective geometric representation generated is a solid computer-aided design (CAD) model.

8. The method of claim 1 wherein generating a respective FEM of each respective geometric representation includes:
for each geometric representation (i) selecting a given mesh generation methodology from amongst a plurality of methodologies, based on an object type represented by the geometric representation and (ii) generating a FEM of the geometric representation using the given mesh generation methodology selected.

9. The method of claim 1 wherein combining each generated respective FEM to create a FEM representing the real-world object includes:
combining each generated respective FEM based on spatial relationships of the groups of points;
identifying one or more overlapping mesh elements of the FEMs combined;
deleting the one or more overlapping mesh elements from the FEMs combined to create a blank space in the FEMs combined; and
remeshing the blank space to create the FEM representing the real-world object.

10. The method of claim 1 wherein the FEM representing the real-world object is a conformal hexahedron FEM.

11. The method of claim 1 wherein the real-world object is a bridge.

12. The method of claim 1 wherein a given component is a structural member.

13. The method of claim 12 wherein the structural member is a deck, a steel girder, a sub-element of a cross-frame, or a sub-element of a transverse diaphragm.

14. The method of claim 1 further comprising:
performing a simulation of the real-world object using the FEM representing the real-world object; and
based on results of performing the simulation, determining at least one of:
a design change to the real-world object; and
structural behavior of the real-world object under load.

15. A system for generating a finite element mesh (FEM) representing a real-world object, the system comprising:
a processor; and
a memory with computer code instructions stored thereon, the processor and the memory, with the computer code instructions, being configured to cause the system to:
partition point cloud data of a real-world object into groups of points, each group corresponding to a component of the real-world object;
generate a respective geometric representation of each group of points;
generate a respective finite element mesh (FEM) of each respective geometric representation generated; and
combine each generated respective FEM to create a FEM representing the real-world object.

16. The system of claim 15 wherein, in partitioning the point cloud data, the processor and the memory, with the computer code instructions, are configured to cause the system to:
perform object detection on the point cloud data to determine each component of the real-world object; and
identify points corresponding to each determined component as the groups of points.

17. The system of claim 15 wherein, in generating a respective geometric representation of each group of points, the processor and the memory, with the computer code instructions, are configured to cause the system to:
process a given group of points to identify unoccupied space in the given group of points;
classify the identified unoccupied space as empty space or occluded space;
solve each of a plurality of parameterization equations using the given group of points and the unoccupied space classified as empty space or occluded space to identify (i) parameter values for each of the plurality of parameterization equations and (ii) a given parameterization equation from amongst the plurality with a lowest error; and
generate a geometric representation based on the given parameterization equation with the lowest error and identified parameter values of the given parameterization equation with the lowest error.

18. The system of claim 15 wherein, in generating a respective FEM of each respective geometric representation, the processor and the memory, with the computer code instructions, are configured to cause the system to:
for each geometric representation (i) select a given mesh generation methodology from amongst a plurality of methodologies, based on an object type represented by the geometric representation and (ii) generate a FEM of the geometric representation using the given mesh generation methodology selected.

19. The system of claim 15 wherein, in combining each generated respective FEM to create a FEM representing the real-world object, the processor and the memory, with the computer code instructions, are configured to cause the system to:
combine each generated respective FEM based on spatial relationships of the groups of points;
identify one or more overlapping mesh elements of the FEMs combined;
delete the one or more overlapping mesh elements from the FEMs combined to create a blank space in the FEMs combined; and
remesh the blank space to create the FEM representing the real-world object.

20. A computer program product for generating a finite element mesh (FEM) representing a real-world object, the computer program product comprising:
one or more non-transitory computer-readable storage devices and program instructions stored on at least one of the one or more storage devices, the program instructions, when loaded and executed by a processor, cause an apparatus associated with the processor to:
partition point cloud data of a real-world object into groups of points, each group corresponding to a component of the real-world object;
generate a respective geometric representation of each group of points;
generate a respective finite element mesh (FEM) of each respective geometric representation generated; and
combine each generated respective FEM to create a FEM representing the real-world object.
